(19) United States
(12) Patent Application Publication
(10) Pub. No.: US 2010/0307577 A1
(43) Pub. Date: Dec. 9, 2010

(54) DYE-SENSITIZED SOLAR CELL AND METHOD FOR MANUFACTURING THE SAME

(75) Inventors: Shinn-Horng CHEN, Taipei City (TW); An-I TSAI, Kaohsiung (TW)

Correspondence Address: PATTERSON THUENTE CHRISTENSEN PEDERSEN, P.A., 4800 IDS CENTER, 80 SOUTH 8TH STREET, MINNEAPOLIS, MN, 55402-2100, US

(73) Assignee: ETERNAL CHEMICAL CO., LTD., Kaohsiung (TW)

(21) Appl. No.: 12/683,913

(22) Filed: Jan. 7, 2010

(30) Foreign Application Priority Data
Jun. 3, 2009 (TW) 098118343

(51) Int. Cl. H01L 31/00; H01L 31/18

(52) U.S. Cl. 136/256; 136/261; 438/69; 257/E21.158

(57) ABSTRACT

A dye-sensitized solar cell and its preparation method are provided. The dye-sensitized solar cell comprises a first electrode, an electrolyte layer and a second electrode. The electrode layer comprises an electrolyte with non-fluidity and the second electrode comprises a conductive material with a proviso of including no substrate. Also, the electrolyte layer and the second electrode are formed in that order on the first electrode.

This application claims priority to Taiwan Patent Application No. 098118343 filed on Jun. 3, 2009, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention provides a solar cell and its preparation method. Particularly, the invention provides a dye-sensitized solar cell using a single substrate and its preparation method.

2. Descriptions of the Related Art

Due to the fast development of technology and economy, requirements of energy sources have increased greatly. Since the inventory of greatly used raw materials, such as rock oil, natural gas, and coal have gradually decreased, there has been a need for the use of other oncoming energy sources to satisfy the increasing requirements of energy sources. Solar energy has become one of the most important sources of oncoming energy due to its advantages, such as low pollution and easy availability.

In the mid 20^{th} century, American Bell Labs first developed a silicon solar cell using the photovoltaic effect of a semiconductor. Although the photoelectric conversion efficiency of a silicon solar cell is better than that of other cells, commercial mass production is still limited due to its drawbacks, such as a complicated process, high product cost, and strict material requirements.

Recently, dye-sensitized solar cells (DSSC) have the development potential for replacing the conventional silicon solar cell due to its advantage, such as its low price, and therefore, has become a research topic of the solar cell.

In general, a DSSC comprises a conductive substrate for providing a current circuit, semiconductor oxides (such as TiO₂) used as an electron transmission layer, a sensitized dye, an electrolyte for transmitting electrons and electron holes, and a package material. The working electrode of DSSC is formed by adsorbing a sensitized dye to the surface of the semiconductor nanocrystal film formed on the conductive substrate. After absorbing the sunlight, the electrons of the sensitized dye transit to their excite state and transfer to the semiconductor nanocrystal film rapidly. The electrons then diffuse to the conductive substrate and transfer to the opposite electrode via an external circuit. The whole transmission process is accomplished by the following steps: the sensitized dye in their oxidized state due to the loss of electrons is reduced by the electrolyte, while the oxidized electrolyte is reduced to its ground state by receiving the electrons of an opposite electrode.

For example, the Swiss M. Grätzel Group developed a kind of DSSC, wherein TiO₂ nanocrystal particles were coated on a conductive substrate of a fluorine-doped tin oxide (FTO) glass (a conductive substrate). Ru-complex (such as N3, N719) sensitized dye was then adsorbed to the conductive substrate via the pore structure of porous film of TiO₂ nanoparticles, and a conductive glass plated with Pt was used as an opposite electrode. An iodine ion (I⁻/I₃⁻) solution was used as an electrolyte to provide the oxidation-reduction reaction necessary for the DSSC. The structures of N3 and N719 were as follows:

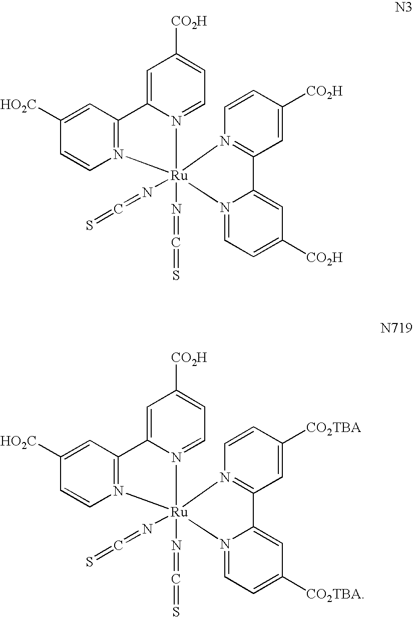

The conventional method for preparing DSSC comprises the following steps: providing two conductive substrates to be prepared as a working electrode and an opposite electrode respectively; attaching and packaging the two electrodes and then injecting an electrolyte therebetween; and finally, sealing the hole to provide the DSSC. More specifically, a layer of semiconductor nanolayer is coated on a conductive substrate first; after curing the semiconductor nanolayer via a sintering process, the conductive substrate coated with the semiconductor nanolayer is placed into a sensitized dye solution so that the sensitized dye can be adsorbed on the semiconductor to provide a working electrode; a layer of conductive substance (such as platinum, carbon black) is formed on another conductive substrate via a suitable method under a vacuum or non-vacuum condition to provide an opposite electrode; the working electrode and the opposite electrode are then attached and packaged; and an electrolyte is injected between the working electrode and the opposite electrode, and finally, the injection hole is sealed.

The conventional method for preparing the DSSC must process two substrates independently which leads to a non-continuous process. As a result, it is inconvenient when preparing a DSSC with a large area, and is also limited to the shape and size of the substrate. It is also inconvenient for the following packaging and attaching steps due to the material properties of the substrates. Moreover, due to process limitations, the conventional preparation method must use two substrates. The substrate cost is almost half of the whole product cost. Therefore, reducing the use of substrates will certainly increase the commercial value of the DSSC.

Furthermore, the conventional preparation method generally uses a liquid electrolyte for the convenience of injecting electrolytes into the packaged working electrode and opposite electrode and ensuring that the vacant space is completely filled with the electrolyte. The commonly used liquid electrolyte is obtained by the following steps: dispersing I₃⁻/I⁻ oxidation-reduction pairs, halogens in chief, into a solvent (such as nitrile, ester, tetrahydrofuran, dimethylformamide, and N-methyl-2-pyrrolidone (NMP)); and adding some additives (such as 4-tert-butylpyridine (TBP), N-methylbenzimidazole (NMBI), LiI, NaI) for modifying the semiconductor oxides (such as TiO₂) to the solvent. Due to the high activity of halogens and high volatility of the solvent, the liquid electrolyte is easy to penetrate to the outside of the cell and thereby cause the cell to lose efficiency and pollute the environment.

Therefore, the invention provides a dye-sensitized solar cell using a single substrate which can be packaged by laminating each component in order, and thus can achieve the objectives of low costs and continuous production.

### SUMMARY OF THE INVENTION

One objective of the invention is to provide a dye-sensitized solar cell, comprising:

a first electrode, comprising a substrate, a conductive layer, a semiconductor layer, and a sensitized dye;

an electrolyte layer, comprising an electrolyte with non-fluidity; and

a second electrode, comprising a conductive material with a proviso of including no substrate;

wherein the electrolyte layer and the second electrode are formed in that order on the first electrode.

Another objective of the invention is to provide a method for manufacturing a dye-sensitized solar cell, comprising:

providing a first electrode; and

forming an electrolyte layer and a second electrode in that order on the first electrode, wherein the electrolyte layer comprises an electrolyte with non-fluidity and the second electrode comprises a conductive material with a proviso of including no substrate.

The aforesaid objectives, features and advantages of the present invention are further described in the following paragraphs with some embodiments.

### BRIEF DESCRIPTION OF THE DRAWINGS

FIG. 1 is an embodiment of the dye-sensitized solar cell according to the present invention.

### DESCRIPTION OF THE PREFERRED EMBODIMENT

The following will describe some embodiments of the present invention accompanying the appended drawing. However, the present invention may be embodied in other embodiments without departing from the characteristics of the invention and should not be limited to the embodiments described in the specification. Furthermore, the size of each component and area in the figures may be exaggerated rather than drawn to scale for clarity.

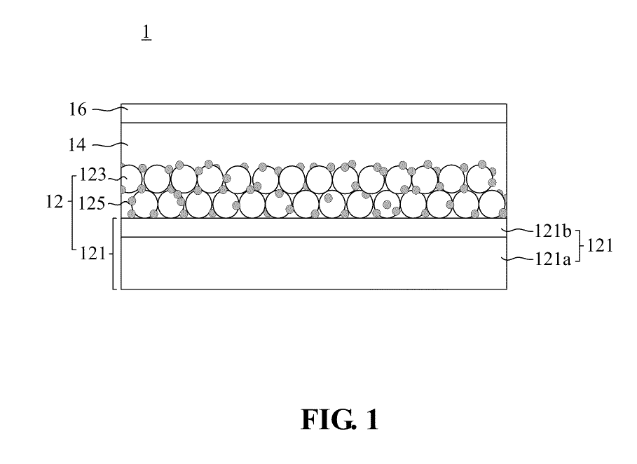

The dye-sensitized solar cell of the invention uses a single substrate and thus can reduce the cost effectively. FIG. 1 shows an embodiment of the dye-sensitized solar cell according to the invention. The dye-sensitized solar cell 1 comprises a first electrode 12, an electrolyte layer 14, and a second electrode 16. The first electrode 12 comprises a substrate 121a, a conductive layer 121b, a semiconductor layer 123, and a sensitized dye 125. The electrolyte layer 14 and the second electrode 16 are formed on the first electrode 12 in turn.

In general, the substrate 121a with the conductive layer 121b coated on the substrate surface is called a conductive substrate 121. The thickness of the conductive substrate 121 is adjusted by the efficiency and application of the final solar cell product. The thickness of the conductive layer 121b ranges from about 300 nm to about 1,000 nm and preferably ranges from about 500 nm to about 800 nm.

The shape and material of the substrate 121a according to the invention are not particularly limited. For example, the shape of the substrate 121a may be a plane, a regular or an irregular three-dimensional shape, such as a triangle, a tetragon, or a polygon; and also an arc with angle or an elliptic cylinder. The material of the substrate 121a may be selected from a group consisting of a metal, a metal alloy, a glass, a plastic, and combinations thereof. When a metal is used, the substrate 121a may be composed of a material selected from a group consisting of iron, aluminum, copper, titanium, gold, alloys thereof, and combinations thereof. When a plastic is used, the substrate 121a may be composed of a material selected from a group consisting of polyester resin, polyacrylate resin, polystyrene resin, polyolefin resin, polycycloolefin resin, polyimide resin, polycarbonate resin, polyurethane resin, triacetyl cellulose (TAC), polylactic acid, and combinations thereof. According to one preferred embodiment of the invention, the substrate 121a is composed of glass. The material of the conductive layer 121b may be a transparent conductive oxide (TCO), such as that selected from a group consisting of fluorine-doped tin oxide (FTO), antimony-doped tin oxide (ATO), aluminum-doped zinc oxide (AZO), indium tin oxide (ITO), and combinations thereof. According to one preferred embodiment of the invention, the material of the conductive layer 121b is FTO.

The material of the semiconductor layer 123 may be any suitable semiconductor oxide and usually with a pore structure. The material of the semiconductor layer 123 is preferred to be a nanoscale semiconductor oxide. For example, the material of the semiconductor layer 123 may be selected from a group consisting of TiO₂, ZnO, SnO₂, In₂O₃, CdS, ZnS, CdSe, GaP, CdTe, MoSe₂, WSe₂, Nb₂O₅, WO₃, KTaO₃, ZrO₂, SrTiO₃, SiO₂, and combinations thereof. The material of the semiconductor layer 123 is preferred to be TiO₂, SnO₂, or ZnO. In some embodiments of the invention, the material of the semiconductor layer 123 is TiO₂.

The thickness of the semiconductor layer 123 generally ranges from about 1 μm to about 50 μm, and preferably ranges from about 4 μm to about 20 μm. If the thickness of the semiconductor layer 123 is too small (such as less than about 1 μm), the efficiency of the prepared dye-sensitized solar cell 1 is poor. On the contrary, if the thickness of the semiconductor layer 123 is too high (such as more than about 50 μm), the semiconductor layer 123 tends to be brittle. According to one preferred embodiment of the invention, the thickness of the semiconductor layer 123 ranges from about 4 μm to about 10 μm.

The sensitized dye 125 used in the dye-sensitized solar cell 1 of the invention may be any sensitized dye known by people with ordinary skill in the art. For example, the sensitized dye 125 may be selected from a group consisting of squaric acid, chlorophyll, rhodamine, azobenzene, cyanine, thiophene, metal complex (such as ruthenium complex), and combinations thereof. In some embodiments of the invention, the sensitized dye 125 is ruthenium complex N719. According to the invention, the sensitized dye 125 is adsorbed to the material surface of the semiconductor layer 123, as shown in FIG. 1.

In the present invention, the electrolyte layer 14 is formed on the first electrode 12 and has a conductivity ranging from about 10⁻² S/cm to about 10⁻⁶ S/cm to provide the necessary efficiency of the cell. The conductivity (K) is defined as follows:

K=G×L/A

wherein G is the electrical conductance (S), L is the distance (cm) between two electrode plates, and A is the surface area (cm²) of the electrode plate.

With respect to the dye-sensitized solar cell, most of the present used electrolytes are liquid electrolytes. However, the organic solvent in the liquid electrolyte tends to volatize to cause changes to the electrolyte formula, and thereby, leads to a loss of cell efficiency or results in a leakage and thereby, polluting the environment. In view of the above defects, the electrolyte layer 14 of the invention comprises an electrolyte with non-fluidity. The aforesaid electrolyte comprises an oxidation-reduction pair and an additive. In general, the electrolyte layer 14 comprising the electrolyte with non-fluidity of the invention, for example, may be prepared as follows: mixing the suitable additive, oxidation-reduction pair and solvent, or adding the suitable additive to the solution of liquid electrolyte to change the solution fluidity, and thus providing an electrolyte solution with non-fluidity; dropping the resulting electrolyte solution on the first electrode 12 and placing it for a period of time for the solution to permeate; after the solution has completely permeated through the first electrode 12, a drying step is performed by removing a portion or all of the solvent to obtain the electrolyte layer 14. The electrolyte with non-fluidity of the invention comprises a colloidal electrolyte, a solid electrolyte, or a combination thereof. The electrolyte with non-fluidity is preferred to be a solid electrolyte.

The colloidal electrolyte suitable for the invention comprises an oxidation-reduction pair, and an additive selected from a group consisting of a filler with a specific surface area of at least about 30 m²/g, a polymer with a molecular weight ranging from about 1,000 to about 5,000,000, and combinations thereof. The specific surface area of the filler preferably ranges from about 30 m²/g to about 160 m²/g, and the molecular weight of the polymer preferably ranges from about 500,000 to about 5,000,000. The content of the additive is at least about 3 wt % to less than about 20 wt %, and preferably ranges from about 3 wt % to about 10 wt %, based on the total weight of the electrolyte.

The solid electrolyte suitable for the invention comprises an oxidation-reduction pair, and an additive selecting from a group consisting of a filler with a specific surface area of at least about 30 m²/g, a polymer with a molecular weight ranging from about 500 to about 4,000,000, and combinations thereof. The content of the additive is at least about 50 wt %, based on the total weight of the electrolyte. The specific surface area of the filler preferably ranges from about 30 m²/g to about 160 m²/g. The additive is preferred to be a polymer with a molecular weight ranging from about 500 to about 4,000,000, and the content of the additive ranges from about 60 wt % to about 95 wt %, based on the total weight of the electrolyte.

The filler suitable for the invention may be selected from a group consisting of TiO₂, ZnO, SnO₂, In₂O₃, CdS, ZnS, CdSe, GaP, CdTe, MoSe₂, WSe₂, Nb₂O₅, WO₃, KTaO₃, ZrO₂, SrTiO₃, SiO₂, and combinations thereof; and is preferably selected from a group consisting of TiO₂, ZnO, SnO₂, SiO₂, and combinations thereof.

The polymer suitable for the invention may be selected from a group consisting of polyether, polyacrylonitrile, polyacrylic, polypyridine, polyphenylamine, polypyrrole, polystyrene, poly(p-benzene), polythiophene, polyacetylene, poly(3,4-ethylbietherthiophene), 3-sec-butyl-4-oxo-tricosanoic acid benzyl ester, polyvinylpyridine, sulfolane, poly(amidoamine) dendritic derivatives, spiro-OMeTAD, poly(N-vinylcarbazole), poly(3,4-ethylenedioxythiophene), poly(ethylene oxide), poly(vinylidene fluoride), polyether urethane, and combinations thereof. According to one preferred embodiment of the invention, the polymer is the polyether urethane of formula (I):

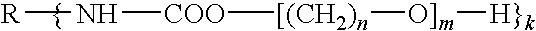

wherein, R represents a substituted or unsubstituted aryl or C₃-C₆ cycloalkyl; n is an integer ranging from 2 to 4; m is an integer ranging from 6 to 50, preferably ranging from 6 to 15; and k is an integer ranging from 2 to 4. According to one preferred embodiment, R in the formula (I) represents tolyl and k is 2, i.e., the polyether urethane has a structure of formula (I₁):

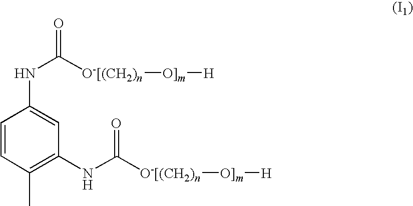

wherein, n is an integer ranging from 2 to 4 and m is an integer ranging from 6 to 15.

According to another preferred embodiment, the polyether urethane is polyethylether toluenediamidioate with the structure of formula (I₂):

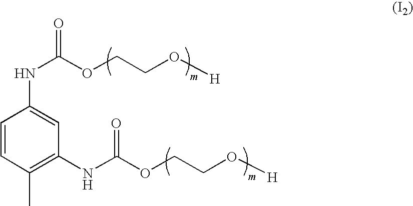

wherein, m is an integer ranging from 6 to 15.

The polyether urethane useful in the invention may be provided by polymerizing a hydroxyl-contained compound with isocyanate. The isocyanate, for example, may be selected from a group consisting of toluene diisocyanate (TDI), methylenediphenylene diisocyanate (MDI), isophoroneiisocyanate (IPDI), dicyclohexanemethylene diisocyanate, xylene diisocyanate, hydrogenated xylene diisocyanate, and combinations thereof, but not limited thereto. The preferred isocyanate is toluene diisocyanate. The hydroxyl-contained compound is a compound containing one or more hydroxyl groups, or a mixture of compounds containing a different number of hydroxyl groups. For example, the hydroxyl-contained compound may be selected from a group consisting of polyethylene glycol (PEG), polypropyleneglycol (PPG), and polytetramethylene glycol (PTMG). The preferred hydroxyl-contained compound is polyethylene glycol.

The oxidation-reduction pair suitable for the dye-sensitized solar cell is not particularly limited, as long as the oxidation-reduction energy level producing by the oxidation-conduction pair can be matched with the highest occupied molecular orbital (HOMO) of the dye. For example, the oxidation-reduction pair may be I₃⁻/I⁻, Br⁻/Br₂, SeCN⁻/(SeCN)₂, or SCN⁻/(SCN)₂. Due to the faster diffusion rate of the iodine ion, the preferred oxidation-reduction pair is I₃⁻/I⁻.

The solvent used for preparing the electrolyte layer 14 can provide an environment for transporting the ions of the formed electrolyte and dissolve the additive (such as the filler and the polymer mentioned above). The solvent useful in the invention usually can be selected from a group consisting of nitrile (such as acetonitrile, methoxypropanenitrile, pentanenitrile), ester (such as ethylene carbonate, propylene carbonate), tetrahydrofuran, dimethylformamide, methylpyrrolidinone, and combinations thereof.

Optionally, polyethylene oxide (PEO) may be added to the colloidal electrolyte or the solid electrolyte according to the invention. The polyethylene oxide is a polymer with linear crystallinity, and has elements of high electronegativity such as oxygen on its main chain that exhibits a polar bonding which is helpful to the dissociation. The polyethylene oxide useful in the invention must have a purity of more than 90% and an average molecular weight ranging from about 500,000 to about 8,000,000. The preferred average molecular weight of the polyethylene oxide ranges from about 4,000,000 to about 5,000,000.

In addition, any known additive also can be optionally added to the colloidal electrolyte or the solid electrolyte according to the invention. Generally, the additive that can modify the relevant properties of the nanoscale semiconductor oxide and improve the cell efficiency is added to the colloidal electrolyte or the solid electrolyte. The commonly used additive may be selected from a group consisting of 4-tert-butylpyridine (TBP), N-methyl-benzimidazole (MBI), 1,2-dimethyl-3-propylimidazolium iodide (DMP II), LiI, and NaI. When a small volume of LiI or NaI are added into the electrolyte, lithium ion (Li⁺) or sodium ion (Na⁺) will adsorb to the surface of semiconductor oxide, and therefore, can reduce the transmitting resistance and the distance of the electrons of conduction band between the adjacent or non-adjacent semiconductor oxides. Consequently, the electron transmission on the surface of semiconductor oxide can be improved, and therefore, the short-current density (J_{SC}) of the solar cell can be improved too. However, the recombination rate of Li⁺-e⁻ and I₃⁻ of the electrolyte will also increase which will reduce the photovoltage (V_{OC}). Therefore, the Fermi level between the lowest unoccupied molecular orbital (LUMO) of the dye and the conduction band of the semiconductor band can be increased by adding 4-tert-butylpyridine (TBP), 1,2-dimethyl-3-propylimidazolium iodide, or N-methyl-benzimidazole, and thus increase the cell voltage. In the consideration of the performance of each cell property, two or more additives can be used in combination.

The second electrode 16 of the invention comprises a conductive material (substantially is a conductive material layer) and is characterized by including no substrate. In the invention, the second electrode 16 is formed on the electrolyte layer 14. Since the second electrode 16 of the invention needs no substrate for supporting and/or for the following package, the substrate amount necessary for the electrode can be greatly reduced when preparing a large area dye-sensitized solar cell, and therefore, the product cost can be reduced. The material of the second electrode 16 can be any suitable conductive material, for example, it may be selected from a group consisting of gold, platinum, an alloy of gold and platinum, silver, aluminum, carbon and its compounds, a transparent conductive oxide, a conductive polymer, and combinations thereof. The transparent conductive oxide (TCO), for example, may be selected from a group consisting of fluorine-doped tin oxide (FTO), antimony-doped tin oxide (ATO), aluminum-doped zinc oxide (AZO), indium tin oxide (ITO), and combinations thereof. The carbon and its compounds, for example, may be selected from a group consisting of carbon nanotube, carbon fiber, carbon nanohorn, carbon black, fullerene, and combinations thereof. The conductive polymer, for example, may be selected from a group consisting of polyaniline (PAN), polypyrrole (PPY), poly-phenylene vinylene (PPV), poly(p-phenylene) (PPP), polythiophene (PT), polyacetylene (PA), poly 3,4-ethylenedioxythiophene (PEDOT), and combinations thereof. In some embodiments of the invention, the material of the second electrode 16 is platinum, PEDOT, a mixture of PEDOT and carbon nanotube, or a mixture of PEDOT and Fullerene.

The dye-sensitized solar cell of the invention can optionally comprise a protective film, such as polyethylene film, a heat shrink film, or a well known package material to keep the cell away from the steam.

In the past, the method for preparing the dye-sensitized solar cell must use two substrates as the electrodes and the two substrates must be processed separately and thereby cause a non-continuous process. The dye-sensitized solar cell of the invention uses a single substrate that can greatly reduce the product cost, and the preparation of each component can be completed in a laminated way that can be operated continuously and is more economical.

The invention further provides a method for manufacturing the dye-sensitized solar cell, comprising the following steps:
(a) providing a first electrode 12; and
(b) forming an electrolyte layer 14 and a second electrode 16 on the first electrode 12 in turn,
   wherein the electrolyte layer 14 comprises an electrolyte with non-fluidity and the second electrode 16 comprises a conductive material with a proviso of including no substrate.

The first electrode 12 of the invention comprises a substrate 121a; a conductive layer 121b; a semiconductor layer 123 and a sensitized dye 125. The first electrode 12 can be prepared by the method well known by people with ordinary skill in the art. For example, the method may comprise the following steps: (1) sputtering a conductive layer 121a on a substrate 121a to form a conductive substrate 121; (2) uniformly coating the conductive substrate 121 with nanoscale semiconductor oxides; (3) performing a curing step, such as a sintering step at 400° C. to 600° C., to form a semiconductor layer 123; (4) immersing the product in the solution of sensitized dye 125 for carrying out the dye adsorption. The coating method of step (2) may be, for example, a knife coating, screen printing, spin coating, or spray coating, but not limited thereto.

The formation in turn in step (b) of the solar cell manufacture process means coating an electrolyte with non-fluidity on the semiconductor layer 123 and the sensitized dye 125 of the first electrode 12 to form an electrolyte layer 14; and then forming the second electrode 16 on the electrolyte layer 14. For example, the method for forming the second electrode 16 may be carried out by performing a metal sputtering process under a vacuum condition; coating metal precursors (such as platinum precursors) on the electrolyte layer 14 under non-vacuum condition and then performing a reduction process of heat treatment; or mixing the conductive polymer or a mixture of conductive polymer and carbon black material in the solvent and coating the resulting solvent on the electrolyte layer 14 and then performing a drying procedure.

The examples below are illustrated to further describe the present invention.

### Example 1

The TiO₂ coating HT (produced by Eternal company; particle size: 20 nm to 50 nm; surface area: 80 m²/g to 120 m²/g) was coated on a FTO glass with a thickness of about 5±1 μm, and then a sintering process at about 500° C. was conducted to form a semiconductor layer.

The FTO glass coated with the semiconductor layer was immersed in the dye solution N719 (produced by Solaronix company) to carry out the dye adsorption for about 12 hours; and a working electrode (a first electrode) of the dye-sensitized solar cell was obtained, Wherein the solvent of N719 are n-propanol and acetonitrile in a weight ratio of 1:1.

After completing the adsorption process and cleaning the obtained working electrode, a solid electrolyte composition comprising 35 wt % polyethylether toluenediamidioate (molecular weight: 2,000 to 4,000), 35 wt % polyethylene oxide (molecular weight: 3,500,000 to 4,000,000), and a mixture of I₃⁻/I⁻ oxidation-reduction pair was coated on the electrode surface. After the coating process was completed, the solvent component of the electrolyte was driven off to form an electrolyte layer.

A platinum metal was then coated on the electrolyte surface by the vacuum sputtering to form an opposite electrode (a second electrode) of the dye-sensitized solar cell, and a dye-sensitized solar cell A using a single substrate according to the invention was obtained. The cell performance of the dye-sensitized solar cell A was tested and the results were recorded in Table 1.

### Example 2

A dye-sensitized solar cell B was produced by using the same methods of Example 1, while the conductive polymer PEDOT was used as the material of the opposite electrode. PEDOT was coated on the surface of the electrolyte layer and cured under a vacuum condition at about 50±10° C. to form the opposite electrode. The cell performance of the dye-sensitized solar cell B was tested and the results were recorded in Table 1.

### Example 3

A dye-sensitized solar cell C was produced by using the same methods of Example 2, while a mixture of the conductive polymer PEDOT and Fullerene was used as the material of the opposite electrode. The content of PEDOT was about 95 wt % and the content of Fullerene was about 5 wt %, based on the total weight of the mixture. The cell performance of the dye-sensitized solar cell C was tested and the results were recorded in Table 1.

### Example 4

A dye-sensitized solar cell D was produced by using the same methods of Example 2, while a mixture of the conductive polymer PEDOT and carbon nanotube was used as the material of the opposite electrode. The content of PEDOT was about 95 wt % and the content of carbon nanotube was about 5 wt %, based on the total weight of the mixture. The cell performance of the dye-sensitized solar cell D was tested and the results were recorded in Table 1.

### Example 5

A dye-sensitized solar cell E was produced by using the same methods of Example 4, while the content of PEDOT was about 90 wt % and the content of carbon nanotube was about 10 wt %, based on the total weight of the mixture. The cell performance of the dye-sensitized solar cell E was tested and the results were recorded in Table 1.

### Cell Performance Test

The test of the solar cell usually uses AM 1.5 (θ=48.2°), the average illumination of the United States of America as the average illumination of sunlight on the earth surface (25° C.), and the light intensity is about 100 mW/cm². Therefore, a simulated sunlight source (AM 1.5) with a light intensity of 100 mW/cm² was used in the test. The test of the dye-sensitized solar cell prepared in the above example was conducted and the current and voltage thereof were measured, and the testing results were recorded in Table 1. AM 1.5 represents Air Mass 1.5, AM=1/cos(θ), and θ represents the angle diverged from the perpendicular incident light.

TABLE 1

| | Open circuit | Short-circuit | | Photoelectric |
|---|---|---|---|---|
| | photovoltage | current density | | conversion |
| Dye-sensitized | Voc^{a} | Jsc^{b} | Fill factor | efficiency |
| solar cell | (V_{oc}) | (mA/cm²) | FF^{c} | η (%) |
| A | 0.42 | 5.31 | 0.47 | 1.06 |
| B | 0.15 | 0.95 | 0.26 | 0.04 |
| C | 0.44 | 7.61 | 0.28 | 0.95 |
| D | 0.54 | 2.23 | 0.47 | 0.56 |
| E | 0.56 | 2.95 | 0.40 | 0.65 |

^{a}open circuit photovoltage (Voc): the voltage measured when the external current of solar cell was broken
^{b}short-circuit current density (Jsc): the value of output current divided by component area when the load of solar cell was zero
^{c}fill factor (FF): the ratio of operating power output and ideal power output of solar cell that represented an important parameter of solar cell property

Given the above, the dye-sensitized solar cell of the invention uses a single substrate that can greatly reduce the product cost. Moreover, according to the invention, the preparation method of the dye-sensitized solar cell can prepare each component in a laminated way in an order that can be continuously operated and has more economical benefit. According to the test results in Table 1, the dye-sensitized solar cell of the invention meets the requirements of enablement and has the utility.

The examples disclosed on the above are used to exemplify the theory of the invention and the benefit thereof and describe the technical features of the invention, and should not be used to limit the claims of the invention. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A dye-sensitized solar cell, comprising:
a first electrode, comprising a substrate, a conductive layer, a semiconductor layer, and a sensitized dye;
an electrolyte layer, comprising an electrolyte with non-fluidity; and
a second electrode, comprising a conductive material with a proviso of including no substrate;
wherein the electrolyte layer and the second electrode are formed in that order on the first electrode.

2. The dye-sensitized solar cell of claim 1, wherein the electrolyte with non-fluidity comprises a colloidal electrolyte, a solid electrolyte, or a combination thereof.

3. The dye-sensitized solar cell of claim 1, the conductivity of the electrolyte ranges from about 10⁻² S/cm to about 10⁻⁶ S/cm.

4. The dye-sensitized solar cell of claim 2, wherein the colloidal electrolyte comprises an oxidation-reduction pair, and an additive selected from a group consisting of a filler with a specific surface area of at least about 30 m²/g, a polymer with a molecular weight ranging from about 1,000 to about 5,000,000, and combinations thereof; wherein the content of the additive is at least about 3 wt %, based on the total weight of the electrolyte.

5. The dye-sensitized solar cell of claim 4, wherein the additive is selected from a group consisting of a filler with a specific surface area ranging from about 30 m²/g to about 160 m²/g, a polymer with a molecular weight ranging from about 500,000 to about 5,000,000, and combinations thereof; and the content of the additive ranges from about 3 wt % to about 10 wt %, based on the total weight of the electrolyte.

6. The dye-sensitized solar cell of claim 4, wherein the filler is selected from a group consisting of TiO₂, ZnO, SnO₂, In₂O₃, CdS, ZnS, CdSe, GaP, CdTe, MoSe₂, WSe₂, Nb₂O₅, WO₃, KTaO₃, ZrO₂, SrTiO₃, SiO₂, and combinations thereof; the polymer is selected from a group consisting of polyether, polyacrylonitrile, polyacrylic, polypyridine, polyphenylamine, polypyrrole, polystyrene, poly(p-benzene), polythiophene, polyacetylene, poly(3,4-ethylbietherthiophene), 3-sec-butyl-4-oxo-tricosanoic acid benzyl ester, polyvinylpyridine, sulfolane, poly(amidoamine) dendritic derivatives, spiro-OMeTAD, poly(N-vinylcarbazole), poly(3,4-ethylenedioxythiophene), poly(ethylene oxide), poly(vinylidene fluoride), polyether urethane, and combinations thereof, and the oxidation-reduction pair is selected from a group consisting of I₃⁻/I⁻, Br⁻/Br₂, SeCN⁻/(SeCN)₂, SCN⁻/(SCN)₂, and combinations thereof.

7. The dye-sensitized solar cell of claim 6, wherein the filler is selected from a group consisting of TiO₂, ZnO, SnO₂, SiO₂, and combinations thereof; and the polyether urethane is polyethylether toluenediamidioate.

8. The dye-sensitized solar cell of claim 2, wherein the solid electrolyte comprises an oxidation-reduction pair, and an additive selecting from a group consisting of a filler with a specific surface area of at least about 30 m²/g, a polymer with a molecular weight ranging from about 500 to about 4,000,000, and combinations thereof; and the content of the additive is at least about 50 wt %, based on the total weight of the electrolyte.

9. The dye-sensitized solar cell of claim 8, wherein the additive is a polymer with a molecular weight ranging from about 500 to about 4,000,000, and the content of the additive ranges from about 60 wt % to about 95 wt %, based on the total weight of the electrolyte.

10. The dye-sensitized solar cell of claim 8, wherein the filler is selected from a group consisting of TiO₂, ZnO, SnO₂, In₂O₃, CdS, ZnS, CdSe, GaP, CdTe, MoSe₂, WSe₂, Nb₂O₅, WO₃, KTaO₃, ZrO₂, SrTiO₃, SiO₂, CdS, and combinations thereof; the polymer is selected from a group consisting of polyether, polyacrylonitrile, polyacrylic, polypyridine, polyphenylamine, polypyrrole, polystyrene, poly(p-benzene), polythiophene, polyacetylene, poly(3,4-ethylbietherthiophene), 3-sec-butyl-4-oxo-tricosanoic acid benzyl ester, polyvinylpyridine, sulfolane, poly(amidoamine) dendritic derivatives, spiro-OMeTAD, poly(N-vinylcarbazole), poly(3,4-ethylenedioxythiophene), poly(ethylene oxide), poly(vinylidene fluoride), polyether urethane, and combinations thereof; and the oxidation-reduction pair is selected from a group consisting of I₃⁻/I⁻, Br⁻/Br₂, SeCN⁻/(SeCN)₂, SCN⁻/(SCN)₂, and combinations thereof.

11. The dye-sensitized solar cell of claim 10, wherein the filler is selected from a group consisting of TiO₂, ZnO, SnO₂, SiO₂, and combinations thereof; and the polyether urethane is polyethylether toluenediamidioate.

12. The dye-sensitized solar cell of claim 1, wherein the conductive material is selected from a group consisting of gold, platinum, an alloy of gold and platinum, silver, aluminum, carbon and its compounds, a transparent conductive oxide, a conductive polymer, and combinations thereof.

13. A method for manufacturing a dye-sensitized solar cell, comprising:
providing a first electrode; and
forming an electrolyte layer and a second electrode in that order on the first electrode, wherein the electrolyte layer comprises an electrolyte with non-fluidity and the second electrode comprises a conductive material with a proviso of including no substrate.

14. The method for manufacturing the dye-sensitized solar cell of claim 13, wherein the first electrode comprises a substrate, a conductive layer, a semiconductor layer, and a sensitized dye.
